(19) United States
(12) Patent Application Publication
(10) Pub. No.: US 2010/0055881 A1
(43) Pub. Date: Mar. 4, 2010

(54) HEAT TREATMENT METHOD FOR COMPOUND SEMICONDUCTOR AND APPARATUS THEREFOR

(75) Inventor: Masahiro SHIMIZU, Nirasaki-shi (JP)

Correspondence Address: OBLON, SPIVAK, MCCLELLAND MAIER & NEUSTADT, L.L.P., 1940 DUKE STREET, ALEXANDRIA, VA, 22314, US

(73) Assignee: TOKYO ELECTRON LIMITED, Tokyo (JP)

(21) Appl. No.: 12/614,168

(22) Filed: Nov. 6, 2009

Related U.S. Application Data
(63) Continuation of application No. PCT/JP08/58566, filed on May 8, 2008.

(30) Foreign Application Priority Data
May 8, 2007 (JP) 2007-123991

(51) Int. Cl. H01L 21/20; H01L 21/263; C23C 16/46; B01J 19/12; C23C 16/52; H01L 21/268; H05B 6/02

(52) U.S. Cl. 438/478; 438/796; 118/725; 250/492.2; 118/697; 219/600; 257/E21.09; 257/E21.333; 257/E21.347

(57) ABSTRACT

A heat treatment method for compound semiconductors includes a step for placing an object to be treated on a stage in a process chamber, and a step for irradiating the surface of the object with an electromagnetic wave having a specific frequency by introducing the electromagnetic wave into the process chamber. A compound semiconductor is heat-treated by the electromagnetic wave irradiated upon the surface of the object to be treated.

This application is a Continuation Application of PCT International Application No. PCT/JP2008/058566 filed on May 8, 2008, which designated the United States.

### FIELD OF THE INVENTION

The present invention relates to a heat treatment method for compound semiconductors such as gallium arsenide (GaAs) and an apparatus therefor.

### BACKGROUND OF THE INVENTION

In general, in the manufacture of semiconductor devices, various heat treatments, e.g., a film forming process, a pattern etching process, an oxidation/diffusion process, a modification process, and an annealing process, are repeatedly performed to manufacture desired devices.

In this case, silicon is generally used as a semiconductor in consideration of cost, processability and the like. In the manufacture of the semiconductor devices, silicon compounds such as silicon oxide, silicon nitride and metal silicide are mainly formed on the silicon substrate. Further, MOSFETs formed by combination of the silicon compounds and metal films and the like are formed on the silicon substrate.

Recently, a compound semiconductor such as GaAs tends to be used instead of the silicon to meet the requirements for an ultrahigh speed semiconductor device and a high power semiconductor device and the development of a semiconductor laser device.

In case of using a compound semiconductor, a compound semiconductor thin film may be formed on a substrate made of a compound semiconductor, or a compound semiconductor thin film may be formed on a semiconductor substrate made of a single substance, e.g., a silicon substrate. Further, in order to form those compound semiconductor thin films, a Metal Organic Vapor Phase Epitaxy (MOVPE) method, a Hydride Vapor Phase Epitaxy (HYPE) method, a Molecular Beam Epitaxy (MBE) method and the like are generally used (see Japanese Patent Laid-open Publication No. 2005-175340).

A basic structure of a general semiconductor device using a compound semiconductor, i.e., a Metal Semiconductor FET (MESFET) will be described with reference to FIG. 9. FIG. 9 is a cross sectional view showing a high electron mobility transistor (HEMT) that is an example of the basic structure of the MESFET using the compound semiconductor. As shown in FIG. 9, a compound semiconductor, e.g., GaAs, substrate is prepared as the semiconductor wafer W serving as an object to be treated. Then, an intrinsic GaAs film T1 having no impurities and an n-type AlGaAs film T2 are sequentially formed on the GaAs substrate. Further, a drain D, a source S and a gate G are formed on the n-type AlGaAs film T2 by metal contact. The MESFET has a heterojunction between two different types of semiconductors and, thus, can achieve a high speed operation.

As described above, the semiconductor devices using the compound semiconductors have an advantage of achieving a high speed operation. However, the semiconductor devices using the compound semiconductors have problems, e.g., crystal defects or interface states at an interface between compounds due to combination of two types of atoms having different lattice constants. In order to solve the problems, the following countermeasures have been implemented: the compound semiconductor is set to have a film thickness equal to or smaller than a critical value not to have its own lattice constant; impurities are doped into the film to reduce the difference in lattice constant; and the defects are confined to other regions except the channel. However, satisfied effects cannot be obtained.

### SUMMARY OF THE INVENTION

In view of the above, the present invention is devised to overcome the above problems, and an object of the present invention is to provide a heat treatment method capable of reducing interface states or crystal defects in the semiconductor devices using the compound semiconductors and an apparatus therefor.

In accordance with a first aspect of the present invention, there is provided a heat treatment method for compound semiconductors, comprising: placing an object to be treated on a stage in a process chamber; and irradiating an electromagnetic wave having a specific frequency on a surface of the object by introducing the electromagnetic wave into the process chamber, wherein a compound semiconductor is subjected to heat treatment by the electromagnetic wave irradiated on the surface of the object.

As described above, the heat treatment of the compound semiconductor is performed by irradiating the electromagnetic wave on the surface of the object to be treated. Accordingly, it is possible to reduce interface states or crystal defects in the semiconductor devices using the compound semiconductors.

In the heat treatment method for compound semiconductors, the heat treatment may be a film forming process for forming a thin film of the compound semiconductor on the object.

In the heat treatment method for compound semiconductors, the thin film of the compound semiconductor may be formed of a material selected from the group consisting of SiC, GaAs, GaN, InN, AlN, BN, InP, ZnO and ZnSe.

In the heat treatment method for compound semiconductors, the heat treatment may be an annealing process for annealing a thin film of the compound semiconductor formed on the object.

In the heat treatment method for compound semiconductors, the object may be a semiconductor substrate made of a single substance.

In the heat treatment method for compound semiconductors, the object may be a compound semiconductor substrate.

In the heat treatment method for compound semiconductors, the compound semiconductor substrate may be formed of a material selected from the group consisting of GaAs, Al₂O₃, SiC, GaN, AlN and ZnO.

In the heat treatment method for compound semiconductors, the frequency of the electromagnetic wave may range from 100 Hz to 10 THz.

In accordance with a second aspect of the present invention, there is provided a heat treatment apparatus for compound semiconductors, comprising: a vacuum evacuable process chamber; a stage disposed in the process chamber to mount thereon an object to be treated; a gas introduction unit for supplying a gas required to perform heat treatment on the object into the process chamber; an electromagnetic wave supply unit for introducing an electromagnetic wave having a specific frequency into the process chamber; and a controller for controlling the electromagnetic wave introduced by the electromagnetic wave supply unit to be irradiated on a surface of the object such that the heat treatment is performed on a compound semiconductor.

The heat treatment apparatus for compound semiconductors may further include a temperature control unit for maintaining the object at a predetermined temperature.

In accordance with a third aspect of the present invention, there is provided a computer readable storage medium storing a program for executing on a computer a heat treatment method for compound semiconductors by using a heat treatment apparatus for compound semiconductors, which includes a vacuum evacuable process chamber, a stage disposed in the process chamber to mount thereon an object to be treated, a gas introduction unit for supplying a gas required to perform heat treatment on the object into the process chamber, and an electromagnetic wave supply unit for introducing an electromagnetic wave having a specific frequency into the process chamber, wherein the electromagnetic wave introduced by the electromagnetic wave supply unit is irradiated on a surface of the object such that a compound semiconductor is subjected to heat treatment.

In the heat treatment method for compound semiconductors and the apparatus therefor in accordance with the embodiments of the present invention, the heat treatment of the compound semiconductor is performed by irradiating the electromagnetic wave having a specific frequency on the surface of the object to be treated. Accordingly, it is possible to reduce interface states or crystal defects in the semiconductor devices using the compound semiconductors.

### BRIEF DESCRIPTION OF THE DRAWINGS

FIG. 1 illustrates a cross sectional view of a heat treatment apparatus in accordance with a first embodiment of the present invention.

FIG. 2 is a plan view showing an arrangement state of thermoelectric conversion devices.

FIG. 3 illustrates a relative permittivity, a loss tangent and dielectric loss of several materials with respect to the microwave of 2.45 GHz.

FIG. 4 illustrates electronegativity difference, dipole moment, spontaneous polarization in several materials including compound semiconductors.

FIG. 5 illustrates a melting point and a general process temperature of several materials including compound semiconductors.

FIG. 6 illustrates a cross sectional view of a heat treatment apparatus in accordance with a second embodiment of the present invention.

FIG. 7 illustrates a cross sectional view of a heat treatment apparatus in accordance with a third embodiment of the present invention.

FIG. 8 is a cross sectional view showing a structure of the CMOS-FET using a compound semiconductor in a channel layer.

FIG. 9 is a cross sectional view showing an example of the basic structure of the MESFET using the compound semiconductor.

### DETAILED DESCRIPTION OF THE EMBODIMENT

Hereinafter, a heat treatment method for compound semiconductors and an apparatus therefor in accordance with an embodiment of the present invention will be described with reference to the accompanying drawings.

### First Embodiment

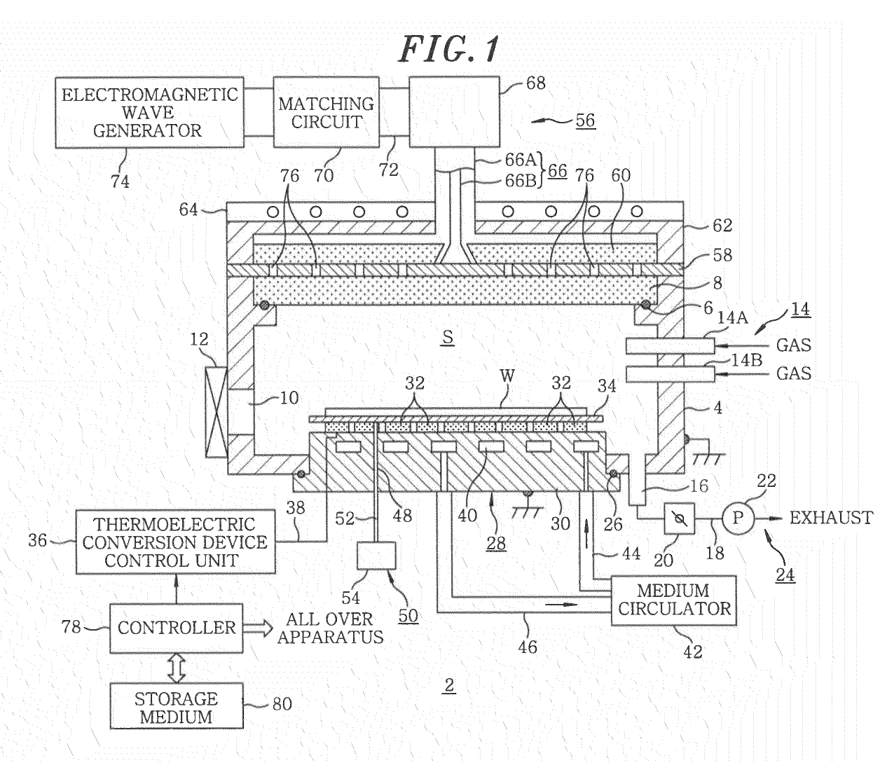

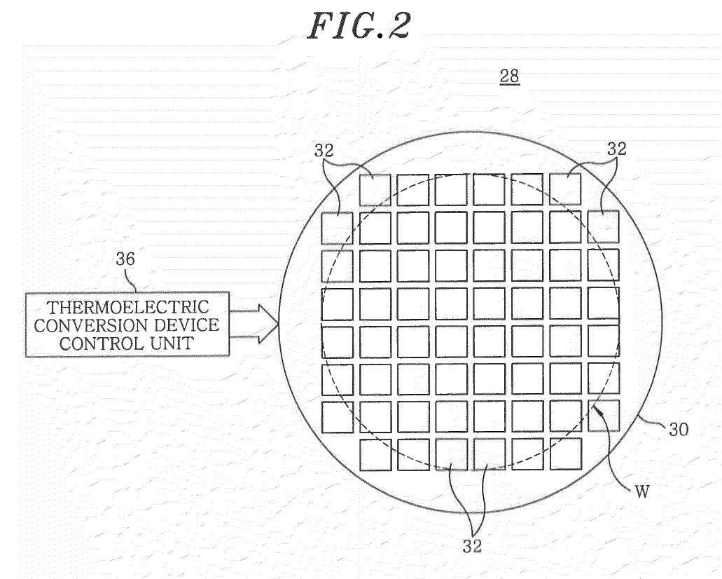

FIG. 1 illustrates a cross sectional view of a heat treatment apparatus in accordance with a first embodiment of the present invention. FIG. 2 is a plan view showing an arrangement state of thermoelectric conversion devices.

As shown in FIG. 1, a heat treatment apparatus 2 for compound semiconductors in accordance with the first embodiment includes a cylindrical process chamber 4 made of, e.g., aluminum. The process chamber 4 has a size capable of accommodating an object to be treated, e.g., a semiconductor wafer W having a diameter of 300 mm. The process chamber 4 is grounded. The process chamber 4 has an opening at its ceiling portion. The opening of the ceiling portion is airtightly sealed with a top plate 8 (to be described later) for transmitting an electromagnetic wave via a seal member 6 such as an O ring. The top plate 8 is made of ceramic such as quartz or aluminum nitride.

Further, the process chamber 4 has an opening 10 at its sidewall. A gate valve 12 is provided at the opening 10 and the gate valve 12 is opened and closed when the semiconductor wafer W serving as an object to be treated is loaded into and unloaded from the process chamber 4. Further, the process chamber 4 is provided with a gas introduction unit 14 for introducing a processing gas into the process chamber 4. The gas introduction unit 14 includes a plurality of gas nozzles (two gas nozzles 14A and 14B in this embodiment) provided at the sidewall of the process chamber 4. The processing gas is supplied into the process chamber 4 via the gas nozzles 14A and 14B. The number of the gas nozzles 14A and 14B is not limited to two and may be increased or decreased depending on the types of the processing gas.

Further, instead of the gas nozzles 14A and 14B, a shower head, which is made of a material transparent to the electromagnetic wave, e.g., quartz, may be provided, as the gas introduction unit 14, immediately below the ceiling portion of the process chamber 4. A gas exhaust port 16 is formed at a bottom peripheral portion of the process chamber 4. The gas exhaust port 16 is connected to a gas exhaust system 24 including a pressure control valve 20 and a gas exhaust pump 22 such as a vacuum pump, which are installed on a gas exhaust passage 18, so that the process chamber 4 can be evacuated to form a depressurized atmosphere, e.g., a vacuum atmosphere, in the process chamber 4. Further, a large opening is formed at a bottom portion of the process chamber 4. A thick stage 28 is airtightly fixed to the opening of the bottom portion by interposing a seal member 26 such as an O ring therebetween, and the stage 28 serves as the bottom portion of the process chamber 4. The stage 28 is also grounded.

The stage 28 includes a stage main body 30 which is made of aluminum and has a large thickness, a plurality of thermoelectric conversion devices 32 which are disposed on the stage main body 30 and serve as a temperature control unit, and a thin disc-shaped mounting plate 34 which is installed on top surfaces of the thermoelectric conversion devices 32. The semiconductor wafer W serving as an object to be treated is mounted directly on the mounting plate 34. Specifically, Peltier devices are used as the thermoelectric conversion devices 32.

The Peltier device is a device made of different conductors or semiconductors that are connected in series by electrodes. When current flows therethrough, heat generation or absorption in addition to Joule heat occurs at a junction of the different conductors or semiconductors. For example, the Peltier device is formed of bismuth telluride (Bi₂Te₃) usable at a temperature of 200° C. or less, silicon germanium (SiGe), lead telluride (PbTe) usable at a higher temperature, or the like. The thermoelectric conversion devices 32 are electrically connected to a thermoelectric conversion device control unit 36 via a lead line 38. The thermoelectric conversion device control unit controls the direction or intensity of the current supplied to the thermoelectric conversion devices in the heat treatment of the wafer W.

FIG. 2 illustrates an arrangement example of the thermoelectric conversion devices 32 formed of Peltier devices. In the example of FIG. 2, sixty thermoelectric conversion devices 32 are provided for the wafer W having a diameter of 300 mm and arranged almost without a gap over the entire backside surface of the mounting plate 34 (top surface of the stage main body 30). When the thermoelectric conversion devices 32 are arranged close to each other as described above, it is possible to uniformly heat the wafer W and the mounting plate 34. The thermoelectric conversion devices 32 may be formed in a circular or hexagonal shape without being limited to a rectangular shape. Here, thermoelectric conversion refers to conversion of thermal energy to electric energy, or conversion of electric energy to thermal energy.

A temperature control may be achieved over the entire region of the thermoelectric conversion devices 32. Alternatively, the entire region of the thermoelectric conversion devices 32 is divided into a plurality of heating zones and an independent temperature control may be achieved for each zone. Further, the thermoelectric conversion devices 32 serving as a temperature control unit are provided if necessary, and may be omitted if electromagnetic wave heating to be described later is sufficient.

Referring back to FIG. 1, a heat medium flow passage 40 is formed inside the stage main body 30 over almost the entire horizontal cross section. The heat medium flow passage 40 is disposed below the thermoelectric conversion devices 32. A cold medium (cold water) is supplied as a heat medium into the heat medium flow passage 40 to decrease the temperature of the wafer W such that the thermoelectric conversion devices 32 are cooled by taking away heat from the bottom surfaces of the thermoelectric conversion devices 32. Further, a hot medium is supplied into the heat medium flow passage 40 to increase the temperature of the wafer W such that the thermoelectric conversion devices 32 are heated by taking away cold heat from the bottom surfaces of the thermoelectric conversion devices 32. The heat medium flow passage 40 is connected to a medium circulator 42 for supplying a heat medium through a heat medium introducing pipe 44 and a heat medium discharging pipe 46. Accordingly, a heat medium is circulatingly supplied from the medium circulator 42 to the heat medium flow passage 40.

Further, the mounting plate 34, which is installed on the thermoelectric conversion devices 32, is made of, e.g., SiO₂, AlN, SiC, Ge, Si, metal or the like. Further, the stage 28 is provided with an elevating mechanism (not shown) for elevating the wafer W. The elevating mechanism includes a plurality of supporting pins, which are vertically movable through the stage main body 30 and the mounting plate 34 to support the wafer W from the bottom, and a driving device for elevating the supporting pins. Further, an electrostatic chuck may be provided on the mounting plate 34.

Further, a through hole 48 is vertically formed in the stage main body 30 and provided with a radiation thermometer 50. Specifically, an optical fiber 52 extending to the bottom surface of the mounting plate 34 is inserted into the through hole 48 in an airtight state to guide radiant light from the mounting plate 34. Further, a radiation thermometer main body 54 is connected to an end portion of the optical fiber 52. Accordingly, the temperature of the mounting plate 34, i.e., the temperature of the wafer W can be measured by light in a specific wavelength band.

Further, an electromagnetic wave supply unit 56 for irradiating an electromagnetic wave toward the wafer W is installed above the top plate 8 of the process chamber 4. An electromagnetic wave having a frequency ranging from 100 MHz to 12 GHz can be used. A case of using a microwave of 2.45 GHz is described as an example.

Specifically, the electromagnetic wave supply unit 56 includes a disc-shaped planar antenna member 58 disposed on the top surface of the top plate 8. A wave retardation member 60 is disposed on the planar antenna member 58. The wave retardation member 60 has a high dielectric constant to reduce the wavelength of a microwave. The planar antenna member 58 is configured as a bottom plate of a waveguide box 62, which is a conductive hollow cylindrical vessel formed to entirely cover an upper surface of the wave retardation member 60. The planar antenna member 58 is disposed to face the stage 28 in the process chamber 4. A cooling jacket 64 is provided on the waveguide box 62 and a coolant flows through the cooling jacket 64 to cool the waveguide box 62.

Peripheral portions of the waveguide box 62 and the planar antenna member 58 are electrically connected to the process chamber 4. A coaxial waveguide 66 includes an outer tube 66A, which is connected to an upper central portion of the waveguide box 62, and an inner conductor 66B, which is connected to a central portion of the planar antenna member through a hole formed at the center of the wave retardation member 60. Further, the coaxial waveguide 66 is connected to an electromagnetic wave generator 74 for generating an electromagnetic wave (microwave) having a frequency of, e.g., 2.45 GHz via a mode transducer 68, a waveguide 72 and a matching circuit 70. Accordingly, the electromagnetic wave (microwave) is propagated to the planar antenna member 58 via the coaxial waveguide 66.

The electromagnetic wave may have other frequencies, e.g., 5.25 GHz, without being limited to 2.45 GHz. The waveguide 72 may be configured as a waveguide having a circular or rectangular cross section or a coaxial waveguide. Further, the wave retardation member 60 may be made of, e.g., aluminum nitride. Further, a magnetron, a klystron or a traveling wave tube may be used as the electromagnetic wave generator 74.

The planar antenna member 58 is formed of, e.g., a silver-plated copper plate or an aluminum plate which is made of a conductive material and has a diameter of 400 to 500 mm and a thickness of 1 to several mm corresponding to a wafer having a diameter of 300 mm. Further, the planar antenna member 58 includes a number of microwave radiation holes 76 formed in long grooves. No particular limitation is imposed on the arrangement of the microwave radiation holes 76. For example, the microwave radiation holes 76 may be arranged in a concentric circular, spiral or radial pattern. The microwave radiation holes 76 may be uniformly arranged over the entire surface of the planar antenna member 58. Generally, the microwave radiation holes 76 have pairs of two holes slightly separated from each other. In each pair, the microwave radiation holes 76 are arranged substantially in a “T” shape. Consequently, the planar antenna member 58 has the so-called radial line slot antenna (RLSA) structure.

Further, the entire operation of the heat treatment apparatus 2 is controlled by a controller 78 including, e.g., microcomputer. A computer program for performing the operation is stored in a storage medium 80 such as a flexible disk, a compact disc (CD), a flash memory or a hard disk. Specifically, the supply and flow rate of gas, the supply and power of microwave, the process temperature, and the process pressure are controlled by the instructions of the controller 78.

Next, a heat treatment method performed by using the heat treatment apparatus 2 will be described. In this embodiment, annealing of a semiconductor substrate having a compound semiconductor thin film will be described as an example of heat treatment.

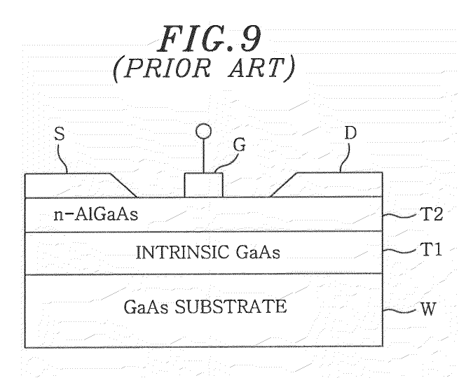

First, a semiconductor wafer W is loaded into the process chamber 4 via the gate valve 12 by using a transfer arm (not shown). Then, the wafer W is mounted on the mounting plate 34 by vertically moving elevating pins (not shown). Then, the process chamber 4 is sealed by closing the gate valve 12. In this case, a semiconductor substrate of a single substance, e.g., a silicon substrate, may be used as the semiconductor wafer W. Alternatively, a compound semiconductor substrate, e.g., a GaAs substrate, may be used as the semiconductor wafer W. Regardless of the type of the substrate, the substrate has a compound semiconductor (e.g., GaAs) thin film formed in a prior process as described in FIG. 9.

Then, the process chamber 4 is evacuated by using the gas exhaust system 24 and gas required for annealing of the compound semiconductor thin film is supplied into the process chamber 4 through the gas nozzles 14A and 14B of the gas introduction unit 14. In this case, the process chamber 4 is maintained at a process pressure at which a plasma is not generated in order to efficiently transfer energy of the irradiated electromagnetic wave to the semiconductor substrate. The process pressure is, e.g., 1.3 Pa or less, or 0.13 Pa or more. Further, inert gas such as Ar, He or N₂ may be used as the gas required for annealing.

The wafer W is heated by supplying electricity to the thermoelectric conversion devices 32 formed of Peltier devices. Further, the electromagnetic wave generator 74 of the electromagnetic wave supply unit 56 generates a microwave. The generated microwave is supplied to the planar antenna member 58 via the waveguide 72 and the coaxial waveguide 66. The microwave having a wavelength reduced by the wave retardation member 60 is radiated through the microwave radiation holes 76 and transmitted through the top plate 8. Accordingly, the microwave is introduced into a processing space S. The microwave introduced into the processing space S is irradiated to the surface of the wafer W.

The wafer W is entirely heated by the irradiation of the microwave. At this time, the compound semiconductor thin film is selectively heated and annealed. Particularly, when the semiconductor wafer W is a semiconductor substrate made of a single substance, e.g., a silicon substrate, the compound semiconductor thin film is selectively heated and annealed without increasing the temperature of the wafer W to the temperature of the thin film.

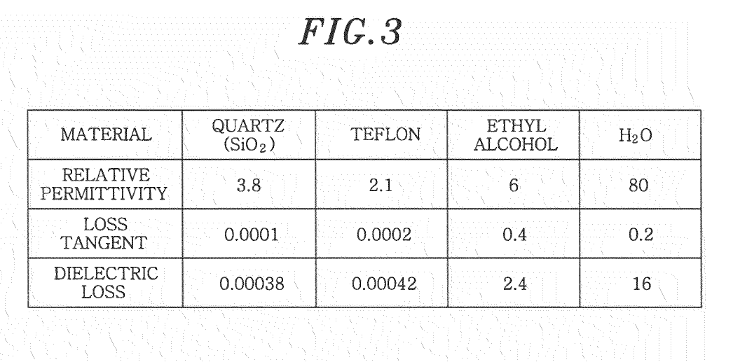

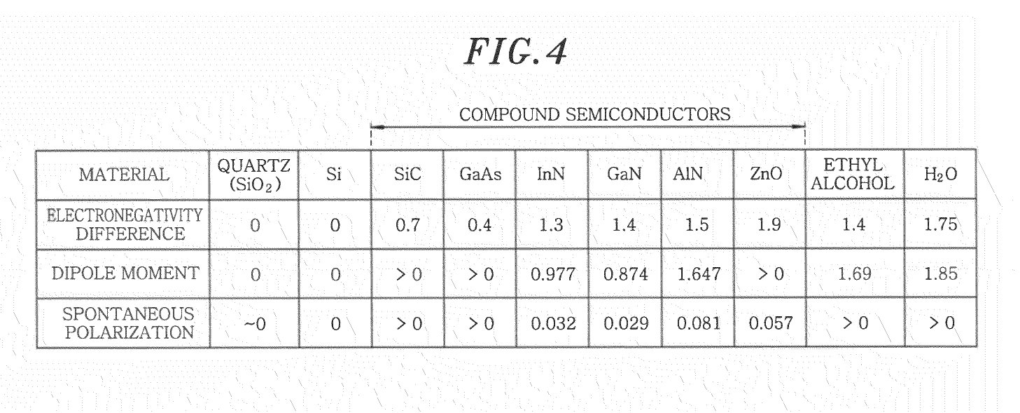

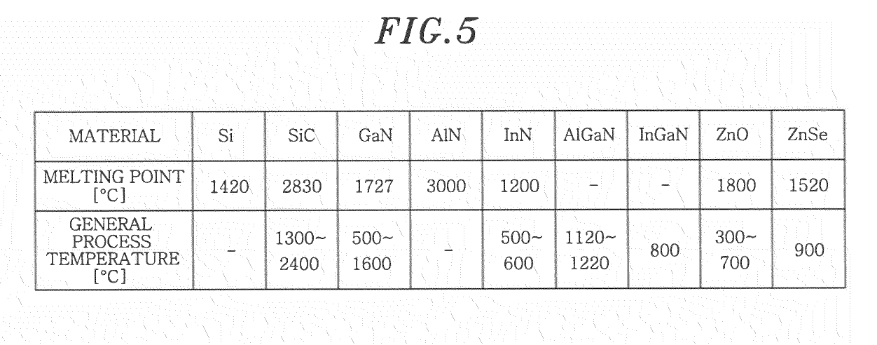

The reason that the compound semiconductor can be selectively heated and the advantages thereof will be described with reference to FIGS. 3 to 5. FIG. 3 illustrates a relative permittivity, loss tangent and dielectric loss of several materials with respect to the microwave of 2.45 GHz. FIG. 4 illustrates electronegativity difference between constituent elements, dipole moment, spontaneous polarization in several materials including compound semiconductors. FIG. 5 illustrates a melting point and general process temperature of several materials including compound semiconductors.

The above-described irradiation of the electromagnetic wave of a high frequency results in induction heating and dielectric heating. In the dielectric heating, as shown in FIG. 3, polar molecules having a high dipole moment, e.g., water (H₂O) and ethyl alcohol, are rapidly heated, whereas nonpolar molecules having no dipole moment, e.g., quartz (SiO₂) and Teflon (registered trademark), are not dielectrically heated. In FIG. 3, energy absorbed by the irradiation of the electromagnetic wave of 2.45 GHz is in proportion to the dielectric loss that is in proportion to the product of a relative permittivity and a loss tangent. Accordingly, the higher the dielectric loss is, the more easily the material is heated. Thus, as shown in FIG. 3, ethyl alcohol having a dielectric loss of 2.4 or H₂O having a dielectric loss of 16 is a material which can be easily heated. This effect is the same as the effect of a microwave oven for home use.

Further, electronegativity difference between constituent atoms, dipole moment, spontaneous polarization in several materials including compound semiconductors used in the embodiment of the present invention are illustrated in FIG. 4. Generally, the polar molecules having a high dipole moment can be easily heated due to a high relative permittivity and high loss tangent. Accordingly, compound semiconductors, e.g., SiC, GaAs, InN, GaN, AlN and ZnO, having a dipole moment larger than zero can be easily heated than quartz and Si having a dipole moment of zero. Particularly, it can be seen that heating InN, GaN and AlN is as easy as heating ethyl alcohol or H₂O.

Thus, when a compound semiconductor thin film is formed on a silicon substrate that is a semiconductor wafer, only a compound semiconductor can be selectively heated by dielectric heating. If the semiconductor wafer is a compound semiconductor substrate, of course, the substrate is also heated.

Further, a melting point and general process temperature of several materials including silicon and compound semiconductors are depicted in FIG. 5. In order to obtain good physical properties, each material needs to be treated at a high temperature appropriate for the material. However, when a silicon substrate is used as a semiconductor wafer, the treatment on the silicon substrate cannot be performed at a temperature higher than a melting point of Si. Further, most of the compound semiconductors shown in FIG. 5 have high melting points, and it may be preferable to treat those semiconductors at a temperature close to or higher than the melting point of Si. In such a case, in the embodiment of the present invention, the compound semiconductor thin film can be selectively heated. Accordingly, only the compound semiconductor thin film can be subjected to heat treatment, e.g., annealing, at a high temperature, which is close to or higher than the melting point of Si in order to obtain good physical properties of the compound semiconductor.

As described above, in the embodiment of the present invention, the heat treatment of the compound semiconductor is performed by irradiating the electromagnetic wave on the surface of the semiconductor wafer W serving as an object to be treated. Accordingly, it is possible to reduce interface states or crystal defects in the semiconductor devices using the compound semiconductors.

Further, although the annealing of the compound semiconductor thin film has been described as the heat treatment, the present invention is not limited thereto and may be applied to formation of the compound semiconductor thin film. In this case, if it is necessary to introduce plural gases separately into the process chamber 4, additional gas nozzles may be installed in addition to the two gas nozzles 14A and 14B.

In this case, for example, Al(CH₃)₃, Al(C₂H₅)₃, Ga(CH₃)₃, Ga(C₂H₅)₃, GaCl(C₂H₅)₂, In(CH₃)₂, In(C₂H₅)₃, Zn(CH₃)₂, Zn(C₂H₅)₂, NH₃, PH₃, AsH₃, H₂Se, SiH₄, CH₄ and the like may be used in combination as source gases depending on the type of compound semiconductor for film formation.

Also in this case, when a compound semiconductor thin film is formed by thermal CVD, the thin film is selectively heated to accelerate the film formation. Further, since the formed compound semiconductor thin film is selectively heated, it is also possible to reduce interface states or crystal defects in the semiconductor devices using the compound semiconductors.

### Second Embodiment

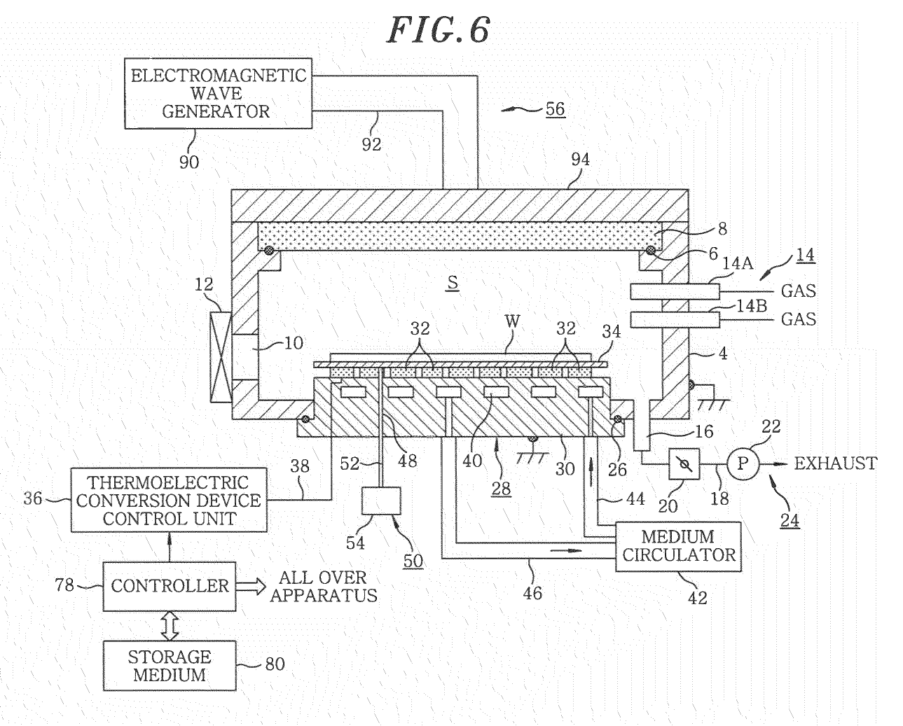

Next, a heat treatment apparatus in accordance with a second embodiment of the present invention will be described. FIG. 6 illustrates a cross sectional view of the heat treatment apparatus in accordance with the second embodiment of the present invention. Further, the same reference numerals will be given to the same components as those in FIG. 1, and a description thereof will be omitted.

In the apparatus shown in FIG. 1, the electromagnetic wave supply unit 56 provides the electromagnetic wave of, e.g., 100 MHz to 12 GHz. On the other hand, the second embodiment employs an electromagnetic wave having a frequency, e.g., 12 GHz to 10 THz, which is higher than that of the electromagnetic wave used in the first embodiment, and having properties close to those of light. Specifically, the electromagnetic wave supply unit 56 includes an electromagnetic wave generator 90 capable of generating an electromagnetic wave having a frequency ranging from, e.g., 12 GHz to 10 THz. For example, a gyrotron may be used as the electromagnetic wave generator 90. The electromagnetic wave having a frequency of 82.9 GHz may be used. Further, the electromagnetic wave having a frequency of 28 GHz, 110 GHz, 168 GHz, 874 GHz or the like may be used.

Further, the electromagnetic wave outputted from the electromagnetic wave generator 90 is introduced to an incident antenna 94 provided on the top plate 8 by a waveguide 92 formed of a rectangle waveguide or an corrugated waveguide. Further, the incident antenna 94 is provided with a plurality of lenses using specular reflection or reflection mirrors (not shown) such that the introduced electromagnetic wave is reflected toward the processing space S in the process chamber 4.

Also in this embodiment, the reflected electromagnetic wave is transmitted through the top plate 8. Accordingly, the electromagnetic wave is introduced into the processing space S and irradiated directly to the surface of the wafer W. Consequently, the compound semiconductor can be selectively heated. Therefore, the same effects as in the first embodiment can be also achieved.

### Third Embodiment

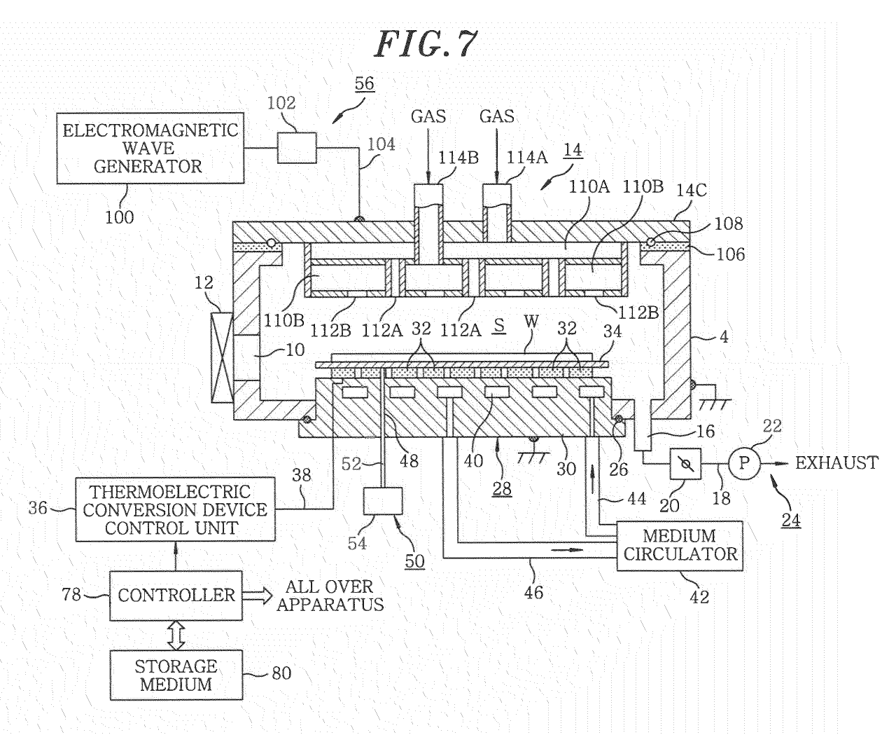

Next, a heat treatment apparatus in accordance with a third embodiment of the present invention will be described. FIG. 7 illustrates a cross sectional view of the heat treatment apparatus in accordance with the third embodiment of the present invention. Further, the same reference numerals will be given to the same components as those in FIG. 1, and a description thereof will be omitted.

In the apparatus shown in FIG. 1, the electromagnetic wave supply unit 56 provides the electromagnetic wave of, e.g., 100 MHz to 12 GHz. On the other hand, the third embodiment employs an electromagnetic wave having a frequency, e.g., 100 Hz to 100 MHz, which is lower than that of the electromagnetic wave used in the first embodiment. Specifically, the electromagnetic wave supply unit 56 includes an electromagnetic wave generator 100 capable of generating an electromagnetic wave having a frequency ranging from, e.g., 100 Hz to 100 MHz. For example, the electromagnetic wave having a frequency of 13.56 MHz may be used. Further, the electromagnetic wave outputted from the electromagnetic wave generator 100 is connected to a ceiling portion of the process chamber 4 by a high frequency cable 104 provided with a matching circuit 102.

At the ceiling portion of the process chamber 4, there is installed a shower head 14C serving as the gas introduction unit 14 via an insulation member 106 and a seal member 108 such as an O ring. Further, the high frequency cable 104 is connected to the shower head 14C. The shower head 14C also serves as an upper electrode. Further, the stage 28 facing the upper electrode serves as a lower electrode.

Further, a plurality of (two in FIG. 7) gas diffusion spaces 110A and 110B which are separated from each other are installed in the shower head 14C. Further, gas injection holes 112A and 112B are formed on the bottom surface of the shower head 14C to communicate with the gas diffusion spaces 110A and 110B, respectively. Further, source gases and the like are introduced through gas inlet ports 114A and 114B communicating with the gas diffusion spaces 110A and 110B, and are diffused in the gas diffusion spaces 110A and 110B to be uniformly injected toward the processing space S through the corresponding gas injection holes 112A and 112B.

In this embodiment, a high frequency voltage of 13.56 MHz is applied between the stage 28 serving as the lower electrode and the shower head 14C serving as the upper electrode. Accordingly, the electromagnetic wave is irradiated directly to the surface of the wafer W. Consequently, the compound semiconductor can be selectively heated. Therefore, the same effects as in the first embodiment can be also achieved.

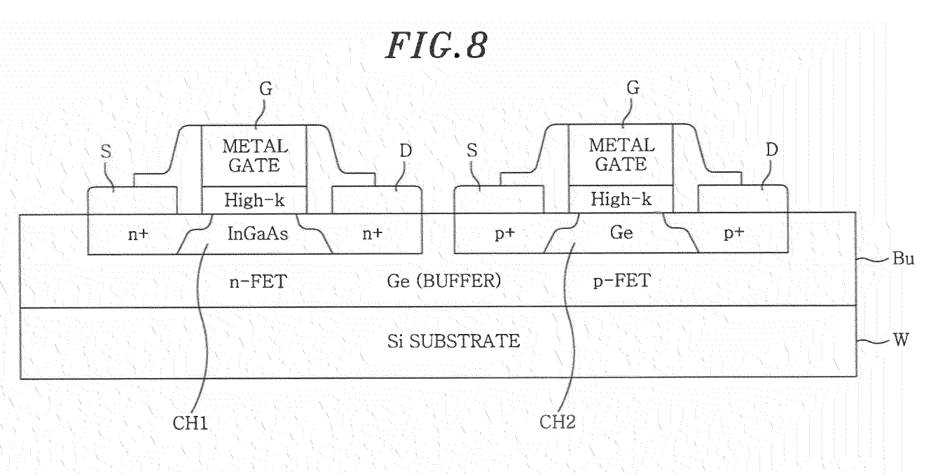

Further, although the semiconductor wafer W having HEMT shown in FIG. 9 has been described as an example in the embodiments, the present invention is not limited thereto, and may be applied to a complementary metal oxide semiconductor FET (CMOS-FET) having a compound semiconductor. FIG. 8 is a cross sectional view showing a structure of the CMOS-FET using a compound semiconductor in a channel layer.

As shown in FIG. 8, in the CMOS-FET, a buffer layer (Bu) made of Ge is formed on the upper surface of the semiconductor wafer W of, e.g., a silicon substrate. The buffer layer (Bu) is divided into isolation regions by shallow trench isolation (STI), and n-FET and p-FET are formed in each isolation region. Further, a compound semiconductor of InGaAs is used in a channel layer (CH1) of the n-FET and a source S and a drain D of n' are formed on both sides of the channel layer (CH1). Further, a metal gate G is formed on the channel layer (CH1) through a high-k insulating layer.

Further, a semiconductor of Ge is used in a channel layer (CH2) of the p-FET and a source S and a drain D of p⁺ are formed on both sides of the channel layer (CH2). Further, a metal gate G is formed on the channel layer (CH2) through a high-k insulating layer. Such device using the compound semiconductor can also perform an energy saving operation in the same way as Si-CMOS-FET.

Further, in addition to the silicon substrate, a germanium substrate may be used as a semiconductor substrate of a single substance.

Further, the compound semiconductor may be formed of any material selected from the group consisting of GaAs, Al₂O₃, SiC, GaN, AlN and ZnO.

Further, the compound semiconductor thin film may be formed of any material selected from the group consisting of SiC, GaAs, GaN, InN, AlN, BN, InP, ZnO and ZnSe.

Further, although the thermoelectric conversion devices are used as a temperature control unit of the heat treatment apparatus in the above embodiments, resistance heaters, heating lamps or the like may be used instead of the thermoelectric conversion devices. Further, although a semiconductor wafer is used as an object to be treated in the above embodiments, the present invention may be applied to a glass substrate, an LCD substrate, a ceramic substrate or the like without being limited thereto.

While the invention has been shown and described with respect to the embodiments, it will be understood by those skilled in the art that various changes and modification may be made without departing from the scope of the invention as defined in the following claims.

What is claimed is:

1. A heat treatment method for compound semiconductors, comprising:
placing an object to be treated on a stage in a process chamber; and
irradiating an electromagnetic wave having a specific frequency on a surface of the object by introducing the electromagnetic wave into the process chamber,
wherein a compound semiconductor is subjected to heat treatment by the electromagnetic wave irradiated on the surface of the object.

2. The heat treatment method of claim 1, wherein the heat treatment is a film forming process for forming a thin film of the compound semiconductor on the object.

3. The heat treatment method of claim 2, wherein the thin film of the compound semiconductor is formed of a material selected from the group consisting of SiC, GaAs, GaN, InN, AlN, BN, InP, ZnO and ZnSe.

4. The heat treatment method of claim 1, wherein the heat treatment is an annealing process for annealing a thin film of the compound semiconductor formed on the object.

5. The heat treatment method of claim 4, wherein the object is a semiconductor substrate made of a single substance.

6. The heat treatment method of claim 1, wherein the object is a compound semiconductor substrate.

7. The heat treatment method of claim 6, wherein the compound semiconductor substrate is formed of a material selected from the group consisting of GaAs, Al₂O₃, SiC, GaN, AlN and ZnO.

8. The heat treatment method of claim 1, wherein the frequency of the electromagnetic wave ranges from 100 Hz to 10 THz.

9. A heat treatment apparatus for compound semiconductors, comprising:
a vacuum evacuable process chamber;
a stage disposed in the process chamber to mount thereon an object to be treated;
a gas introduction unit for supplying a gas required to perform heat treatment on the object into the process chamber;
an electromagnetic wave supply unit for introducing an electromagnetic wave having a specific frequency into the process chamber; and
a controller for controlling the electromagnetic wave introduced by the electromagnetic wave supply unit to be irradiated on a surface of the object such that the heat treatment is performed on a compound semiconductor.

10. The heat treatment apparatus of claim 9, further comprising a temperature control unit for maintaining the object at a predetermined temperature.

11. A computer readable storage medium storing a program for executing on a computer a heat treatment method for compound semiconductors by using a heat treatment apparatus for compound semiconductors, which includes a vacuum evacuable process chamber, a stage disposed in the process chamber to mount thereon an object to be treated, a gas introduction unit for supplying a gas required to perform heat treatment on the object into the process chamber, and an electromagnetic wave supply unit for introducing an electromagnetic wave having a specific frequency into the process chamber,
wherein the electromagnetic wave introduced by the electromagnetic wave supply unit is irradiated on a surface of the object such that a compound semiconductor is subjected to heat treatment.
